(19) United States
(12) Patent Application Publication
(10) Pub. No.: US 2023/0011072 A1
(43) Pub. Date: Jan. 12, 2023

(54) SEMICONDUCTOR LASER DEVICE

(71) Applicant: Mitsubishi Electric Corporation, Tokyo (JP)

(72) Inventors: Ryosuke MIYAGOSHI, Tokyo (JP); Naoki NAKAMURA, Tokyo (JP); Naoki KOSAKA, Tokyo (JP); Kosuke SHINOHARA, Tokyo (JP)

(73) Assignee: Mitsubishi Electric Corporation, Tokyo (JP)

(21) Appl. No.: 17/785,136

(22) PCT Filed: Feb. 28, 2020
(86) PCT No.: PCT/JP2020/008260

§ 371 Date: Jun. 14, 2022

(51) Int. Cl. H01S 5/00; H01S 5/02253; H01S 5/10; H01S 5/0231; H01S 5/02255; H01S 5/0237

(52) U.S. Cl. CPC H01S 5/0014; H01S 5/02253; H01S 5/1014; H01S 5/0231; H01S 5/02255; H01S 5/0237; H01S 5/101

(57) ABSTRACT

Provided are a lens, a stem, an LD chip to emit laser light with a beam center directed along a mounting surface of the stem, and a PD chip having a reflective surface formed with a dielectric multilayer film on its surface, reflecting the laser light emitted from the LD chip toward the lens, and measuring an amount of the laser light, wherein the LD chip is provided with a waveguide portion having a tip portion that is formed on a side of a front end face and has a width of 0.5 to 0.7 μm, and having a tapered portion that is connected to the tip portion and becomes narrower toward the tip portion at a gradient of 0.018 to 0.033.

### TECHNICAL FIELD

The present application relates to a semiconductor laser device.

### Background Art

In a semiconductor laser device for communication, it is necessary to control an output of a semiconductor laser element (LD chip) with high accuracy. Therefore, a semiconductor laser device has been proposed in which forward light emitted from an LD chip is bent in a vertical direction by using a photodiode element (PD chip) for monitoring installed at an angle of 45° with respect to the top surface of the stem (refer to, for example, Patent Document 1). When the laser light is reflected by the PD chip, the reflectivity changes according to the incident angle, and thus in order to maintain the communication quality, it is desirable to narrow the spread angle of the beam in order to suppress the change in the incident angle. On the other hand, in order to omit a lens system for focusing the light, an LD chip called a spot-size converter laser (SSC laser) is sometimes used (refer to, for example, Patent Document 2).

### CITATION LIST

### Patent Document

Patent Document 1: Japanese Unexamined Patent Application Publication No. 2011-192909 (paragraphs 0017 to 0024, FIG. 2 to FIG. 3, and paragraph 00324)

Patent Document 2: Japanese Unexamined Patent Application Publication No. 2005-260223 (paragraphs 0016 to 0030, and FIG. 1 to FIG. 2)

### SUMMARY OF INVENTION

### Problems to be solved by Invention

In the SSC laser, the spot size is narrowed by forming a waveguide such that the width thereof is narrower toward the emission side. In this case, in order to narrow the spot size so that the lens system can be omitted, it is necessary to narrow the spread angle from the center of the beam to about 5°, and it is necessary to narrow the width of a tip portion to 0.4 μm, for example. In this case, even a slight variation in the width causes a large change in the spread angle. Therefore, if the output of the SSC laser is merely reflected by the PD chip, there is a concern about deterioration in communication quality due to variations in laser output control and the amount of emitted light, and it is difficult to achieve both miniaturization and reliability

The present application discloses a technique for solving the above-mentioned problems, and an object thereof is to provide a semiconductor laser device having high reliability in a compact size.

### Means for solving Problems

The semiconductor laser device disclosed in the present application includes a lens, a stem disposed so as to be opposed to the lens with a space therebetween, a semiconductor laser element to emit laser light with a beam center directed along an opposed surface of the stem to the lens, and a photodiode element having a reflective surface formed with a dielectric multilayer film on its surface, reflecting the laser light emitted from the semiconductor laser element toward the lens, and measuring an amount of the laser light, wherein the semiconductor laser element is provided with a waveguide portion having a tip portion that is formed at an end portion on an emission side of the laser light and has a width of 0.5 to 0.7 μm, and having a tapered portion that is connected to the tip portion and becomes narrower toward the tip portion at a gradient of 0.018 to 0.033.

### Effect of Invention

According to the semiconductor laser device disclosed in the present application, since the configuration is adopted in which narrowing of the spread angle can be performed such that the change of the spread angle is a negligible degree even if there is dimensional variation, it is possible to obtain a semiconductor laser device having high reliability in a compact size.

### BRIEF DESCRIPTION OF DRAWINGS

FIG. 1A and FIG. 1B are a cross-sectional view of an LD chip constituting a semiconductor laser device and a graphical view showing a relationship between a tip width and a spread angle, according to Embodiment 1, respectively.

FIG. 2A and FIG. 2B are a plan view of the semiconductor laser device and a view of a cross section perpendicular to a mounting surface of a stem, including a beam center, according to Embodiment 1, respectively.

FIG. 3 shows a cross section perpendicular to the mounting surface of the stem of the semiconductor laser device and perpendicular to an arrangement direction of the LD chip and a PD chip on the mounting surface, according to Embodiment 1.

FIG. 4A and FIG. 4B are schematic views showing a relationship between the spread angle of a beam and a required size of the PD chip and a relationship between the spread angle of the beam and an incident angle on the PD chip, respectively.

FIG. 5 is a cross-sectional view of an LD chip constituting the semiconductor laser device according to a variation of Embodiment 1.

FIG. 6A and FIG. 6B are a plan view of a semiconductor laser device and a view of a cross section perpendicular to the mounting surface of the stem, including the beam center, according to Embodiment 2, respectively.

FIG. 7 shows a cross section perpendicular to the mounting surface of the stem of the semiconductor laser device and perpendicular to the arrangement direction of the LD chip and the PD chip on the mounting surface, according to Embodiment 2.

FIG. 8A and FIG. 8B are a plan view of a semiconductor laser device and a view of a cross section perpendicular to the mounting surface of the stem, including the beam center, according to Embodiment 3, respectively.

FIG. 9A and FIG. 9B are a plan view of a semiconductor laser device and a view of a cross section perpendicular to the mounting surface of the stem, including the beam center, according to Embodiment 4, respectively.

FIG. 10 shows a cross section perpendicular to the mounting surface of the stem of the semiconductor laser device and perpendicular to the arrangement direction of the LD chip and the PD chip on the mounting surface, according to Embodiment 4.

FIG. 11A and FIG. 11B are a plan view of a semiconductor laser device and a view of a cross section perpendicular to the mounting surface of the stem, including the beam center, according to Embodiment 5, respectively.

FIG. 12A and FIG. 12B are a plan view of a semiconductor laser device and a cross-sectional view perpendicular to the mounting surface of the stem and parallel to the beam center, according to Embodiment 6, respectively.

FIG. 13A and FIG. 13B are a view of a cross section perpendicular to the mounting surface of the stem of the semiconductor laser device and perpendicular to the arrangement direction of the LD chip and the PD chip on the mounting surface, and a cross-sectional view of the LD chip, according to Embodiment 6, respectively.

FIG. 14A and FIG. 14B are a plan view and a view of a cross section perpendicular to the mounting surface of the stem and parallel to the beam center of a semiconductor laser device according to Embodiment 7, respectively.

### MODES FOR CARRYING OUT INVENTION

A semiconductor laser device according to each embodiment of the present application will be described with reference to the drawings. The same or corresponding components are denoted by the same reference numerals, and repetitive descriptions may be omitted.

### Embodiment 1

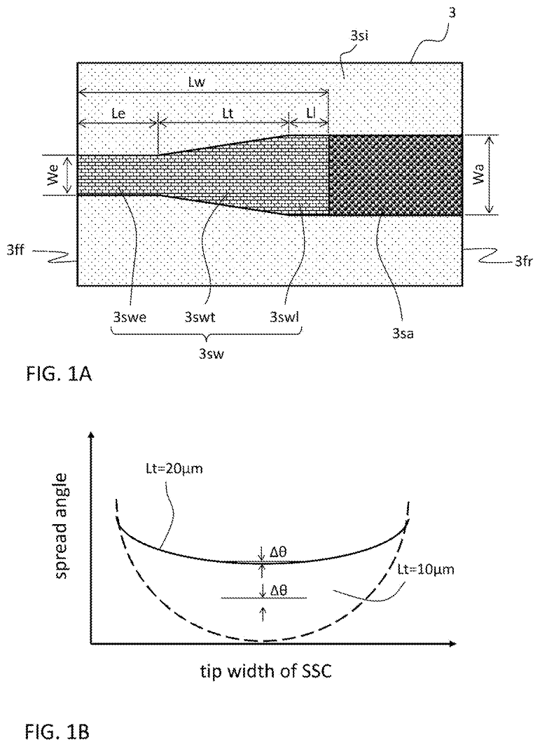

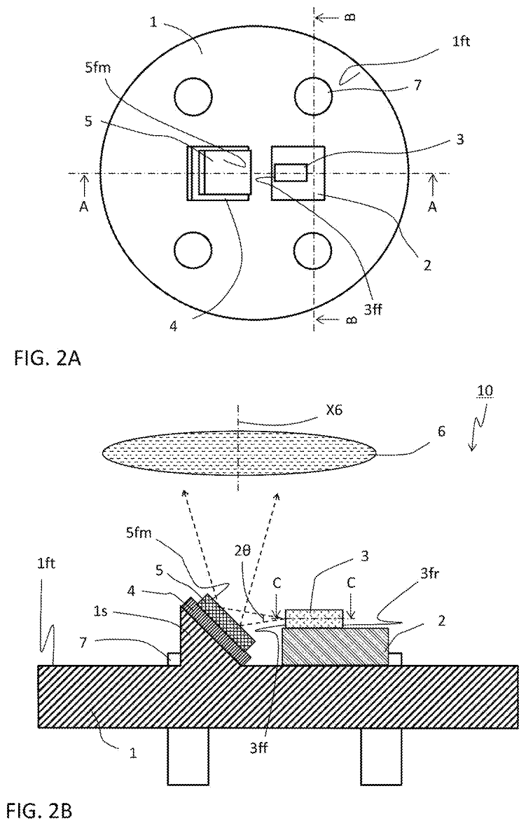

FIG. 1 to FIG. 4 are views for explaining a configuration of a semiconductor laser device according to Embodiment 1, and FIG. 1 includes a cross-sectional view (FIG. 1A) taken along the line C-C of FIG. 2B, which will be described later, to show a shape of a waveguide portion of an LD chip constituting the semiconductor laser device, and a graphical view (FIG. 1B) showing a relationship between a tip width shown in FIG. 1A and a spread angle of emitted light. FIG. 2 includes a plan view (FIG. 2A) excluding the lens as viewed from a side of a mounting surface of a stem of the semiconductor laser device, and a view of a cross section (FIG. 2B) taken along the line A-A of FIG. 2A as the cross section perpendicular to the mounting surface of the stem, including a beam center.

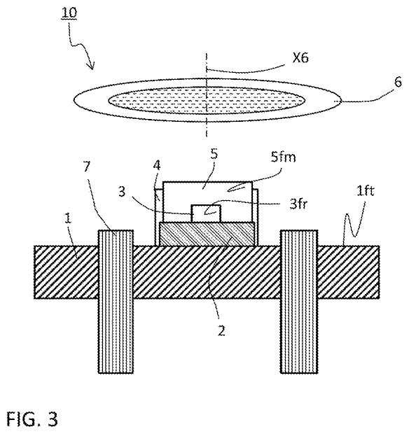

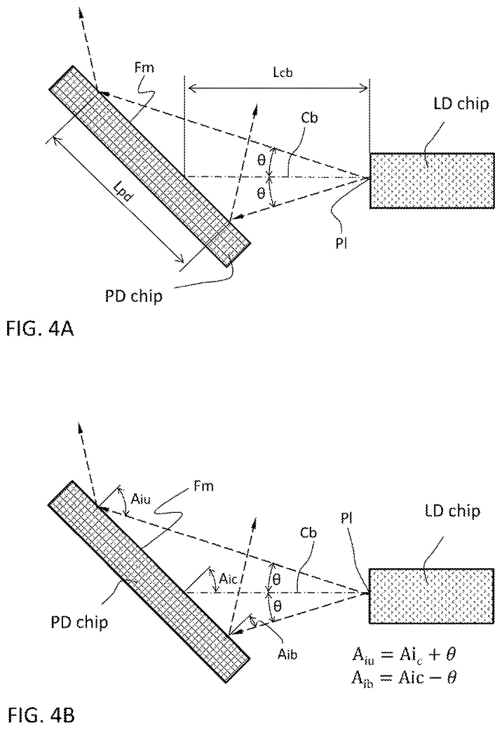

FIG. 3 is a view of a cross section taken along the line B-B in FIG. 2A as the cross section perpendicular to the mounting surface of the stem of the semiconductor laser device and perpendicular to an arrangement direction of the LD chip and a PD chip on the mounting surface. Further, FIG. 4 includes a schematic view showing a relationship between a spread angle of a beam and a required size of the PD chip, in which the LD chip and PD chip portion of FIG. 2B are extracted and drawn, and a schematic view similar to FIG. 4A showing a relationship between the spread angle of the beam and an incident angle on the PD chip.

Although the semiconductor laser device 10 of the present application is characterized by a configuration of a waveguide portion 3sw (FIG. 1) of the LD chip 3, prior to the detailed description thereof, a basic configuration of the semiconductor laser device 10 will be described with reference to FIG. 2A, FIG. 2B, and FIG. 3. The semiconductor laser device 10 is configured such that the LD chip 3 opposed to a lens 6 with a distance therebetween is mounted via a submount 2 on the mounting surface 1ft of the stem 1, and the PD chip 5 is mounted via a submount 4 on an inclined portion is inclined by 45° with respect to the mounting surface 1ft.

A main body of the stem 1 is, for example, a disc of a cold rolled steel sheet (SPCC: Steel Plate Cold Commercial), and a through hole for inserting a lead 7 is formed. The lead 7 is made of, for example, an alloy of Ni—Fe, inserted into the through hole, and fixed to the main body by a low melting point glass such that part of the lead 7 is exposed from the mounting surface 1ft. The submount 2 and the submount 4 are, for example, ceramic substrates, and the LD chip 3 and the PD chip 5 are fixed to conductors of the submount 2 and the submount 4 by brazing material such as solder, respectively. The conductor of the submount 4 is connected to the lead 7 by a wire of gold or the like, and an anode electrode of the PD chip 5 is connected to the lead 7 by the wire of gold or the like. The conductor of the submount 2 is also connected to the lead 7 by the wire of gold or the like.

A surface (reflective surface 5fm) of the PD chip 5 is coated with a highly reflective film made of a dielectric multilayer film, which is designed to receive part of arriving light and to reflect the rest. Therefore, when the laser light emitted from the LD chip 3 reaches the reflective surface 5fm of the PD chip 5, part of the laser light is received to cause a detection current, and the rest is reflected and is directed up toward the lens 6 positioned in the vertical upward direction with respect to the mounting surface 1ft. The laser light passed through the lens 6 is imaged on an object such as an optical fiber and output as a signal for communication.

Here, the highly reflective film such as a combination of silicon (Si) and silicon dioxide (SiO₂) is formed by alternately laminating films of materials having different refractive indices, and the film thickness is determined so as to satisfy the equation of Bragg reflection for light having a wavelength of 1310 nm. For example, when three pairs of Si—SiO₂ film are laminated, the reflectivity is approximately 95%. In this case, 95% of the laser light incident on the PD chip 5 is reflected in the vertical direction, the remaining 5% is received (absorbed) by the PD chip 5, and the detection current corresponding to the amount of received light is output.

Although the basic configuration of the semiconductor laser device 10 has been described so far, problems in the basic configuration will be described prior to a description of the characteristic configuration. In general, the light emitted from the LD chip has a spread, for example, the spread being 40° on each side with respect to the beam center. When the distance between the LD chip and the PD chip is long, the light from the LD chip spreads widely until it reaches the PD chip, and part of the light does not hit the surface of the PD chip at the edge of the light. This is called vignetting of light.

In order to solve this problem, it is conceivable to adopt a configuration in which the emission end of the LD chip is disposed to direct directly toward the lens without interposing the PD chip. However, in this case, the distance from the LD chip to a top surface of the stem is increased, so that the lead and the gold wire needs to be lengthened, which is a cause of a parasitic inductance, thereby deteriorating a modulation characteristic. Although it is possible to shorten the lead by lowering mounting height of the LD chip to make the chip closer to the top surface of the stem, in a case where a typical assembly apparatus for the semiconductor laser device is used, the collet for sucking the chip and the stem interfere with each other when the chip is mounted, and thus it is not a realistic solution.

Although the deterioration of the modulation characteristic can be suppressed by mounting a built-in substrate, it is desirable to eliminate the built-in substrate because it causes an increase in the cost. Further, when the LD chip emits the light directly toward the lens, it is necessary to emit monitor light from the opposite end face thereof for output control. In this case, when the ratio of the monitor light to the signal light changes due to some reason, tracking performance deteriorates (tracking error).

In contrast, in the basic configuration used in the semiconductor laser device 10 of the present application, since the laser light emitted from the LD chip 3 is reflected toward the lens 6 by the PD chip 5 that can monitor the light, the tracking error problem is solved, but there is the problem of the vignetting described above. Therefore, in order to apply all the spread light to the surface of the PD chip, it is conceivable that the distance between the LD chip and the PD chip is shortened as much as possible or the spread angle of the light emitted from the LD chip is narrowed.

Note that the problem of vignetting only can be solved by increasing the area of the PD chip. For example, as shown in FIG. 4A, it is defined that the distance from a light emitting point PI at a beam center Cb to the PD chip is L_{cb} and the spread angle is θ. Then, in the PD chip disposed at an inclination of 45°, a length L_{pd} of the reflective surface Fm necessary for reflecting the laser light is expressed by the following equation (1). Note that the reflective surface 5fm in the semiconductor laser device 10 of the present application corresponds to a reflective surface Fm in FIG. 4.

L_{pd}=2√2×L_{cb}×tanθ/(1−tan²θ) (1)

That is, it is possible to suppress the length L_{pd} required for the PD chip by merely reducing the distance L_{cb} without narrowing the spread angle θ. However, the distance between the LD chip and the PD chip is limited to 0.5 mm in consideration of the interference at the time of chip mounting, and when the spread angle θ is 40°, L_{pd} is as large as 4 mm, but it is not realistic to make the distance shorter than that, and thus it is difficult to solve the problem only by shortening the distance. Further, when the PD chip is enlarged, not only the cost increases but also miniaturization of the device is more difficult. Furthermore, in either case, when the laser light with the spread is incident on the surface of the PD chip, a difference occurs in the angle of incidence within the reflective surface.

When the inclination of the PD chip is 45°, as shown in FIG. 4B, an incident angle A_{ic} of the beam center Cb with respect to the reflective surface Fm of the PD chip is 45°. On the other hand, in the case where the light spreads out at a spread angle θ on both the upper and lower sides with respect to the beam center Cb, the incident angle A_{ib} of the light toward the reflective surface Fm at the end on the stem side (lower side in the figure) is A_{ic}−θ, the incident angle Aᵢᵤ of the light at the end on the lens side is A_{ic}+θ, and the difference in the incident angles is 2θ. Therefore, as described in the background art, the distribution of reflectivity occurs, and the communication quality deteriorates.

Therefore, a method for reducing the spread angle of light from the LD chip is realistic. However, although the narrowing of the spread angle is performed by using the SSC, as mentioned in the background art, if the structure of the narrowing disclosed in Patent Document 2 is simply applied, the following problems occur. This problem in addition to the structure of a typical LD chip will be described.

In a typical LD chip, an active layer (corresponding to the active layer 3sa in FIG. 1A) is formed with a constant width in the direction of a resonator, or a transparent waveguide portion is formed with the same width as the active layer portion. Here, the transparent waveguide is a path for bringing the light emitted from the active layer to an emission end face while confining the light by forming the waveguide in the waveguide direction with a material having a refractive index larger than that of a substrate, and for example, InGaAsP is used.

On the other hand, it is known that the SSC is provided in the waveguide as a technique for narrowing the spread angle of the laser light. When the SSC is formed, it is known that the width of the active layer portion is made tapered in the middle of the direction of the resonator, which will be described later. Alternatively, it is known that the transparent waveguide is tapered to be thin in the middle of the direction of the resonator.

Here, for example, when the width of the active layer is constant at 1.1 μm in the direction of the resonator, the laser light is emitted to both sides of the beam center at a spread angle θ of about 40°, and the difference between the incident angles is 80°. On the other hand, in the typical SSC as disclosed in Patent Document 2, the width on the emission end side is narrowed down to 0.4 μm, thereby narrowing the spread angle θ down to 5 to 6°, and if this is applied to the above-described basic configuration, in addition to a solution for the vignetting problem, the difference between the incident angles can be suppressed to about 11°, leading to a reliable solution.

However, when dimensional variation in mass production is taken into consideration, it has been found that the variation in the spread angle θ becomes large in a typical structure of the narrowing, the yield is lowered, and the communication quality may be adversely affected. Therefore, the influence on the change of the spread angle θ due to the dimensional variation and the influence on the distribution of the reflectivity due to the spread angle θ were examined, and it was determined which portion of the SSC has the influence on the spread angle θ and its variation. By setting the spread angle θ within a certain range, the change of the spread angle θ can be suppressed and high communication quality can be maintained even if manufacturing variation occurs. This will be described in detail below.

Basically, as shown in FIG. 1A, the LD chip 3 constituting the semiconductor laser device 10 of the present application has the waveguide portion 3sw constituting the SSC, formed on the side of a front end face 3ff with respect to the active layer 3sa having a width Wa disposed on the side of a rear end face 3fr. Note that the active layer 3sa and the waveguide portion 3sw are sandwiched by insulating layers 3si from both sides.

The waveguide portion 3sw includes a straight portion 3swl having the same width as the active layer 3sa and adjacent thereto, a tip portion 3swe disposed on the side of the front end face 3ff, and a tapered portion 3swt formed between the straight portion 3swl and the tip portion 3swe. Then, the width Wa of the active layer 3sa is set to 11 μm, and the width We of the tip portion 3swe is set to 0.60 μm in order to achieve the spread angle θ of 20°.

On the other hand, the dimensional variation in the mass production of the LD chip is at the level of 0.05 μm, and the width We of the tip portion 3swe of the LD chip actually produced is to be distributed between 0.55 to 0.65 μm with respect to a design dimension 0.60 μm of the width We of the tip portion 3swe described above.

Here, the width Wa is set to 1.1 μm, the tip width We is set to 0.60 μm, and a waveguide length Lw is set to 50 μm, and using the length of the tapered portion 3swt (the taper length Lt) as a parameter, the amount of change Δθ of the spread angle θ when the above-described dimensional variation occurs at the tip portion 3swe was calculated. Then, it has been found that the behavior of the amount of change Δθ greatly depends on the taper length Lt. It has been found that, when the taper length Lt is set to 10 μm, as shown in FIG. 1B, the amount of change Δθ is 5° or more when the variation of the tip width We is ±0.05 μm, but when the taper length Lt is set to 20 μm, the amount of change Δθ is 2° or less.

As a result of more detailed examination, it has been found that decreasing a gradient Gt by increasing the taper length Lt rather than the taper length Lt itself has an effect of suppressing the amount of change Δθ with respect to the dimensional variation. Note that the gradient Gt is defined by an equation (2).

Gt=(Wa−We)/Lt (2)

According to the definition of the equation (2), it has been found that, when the gradient Gt is 0.05, the amount of change Δθ is 5° or more, and when the gradient Gt is 0.025, the amount of change Δθ is 2° or less.

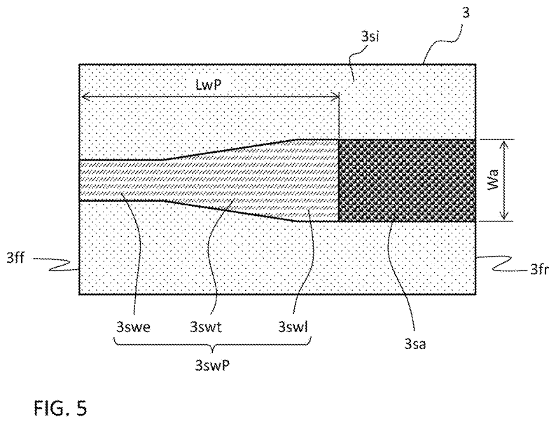

As for the waveguide length Lw, the dimensional variation is increased to ±10 μm when the transparent waveguide (waveguide portion 3swP in FIG. 5) to be described later is considered, but it has been found that the length should be set within a range of 50 μm ±10 μm. Further, it has been found that the influence of the length Le of the tip portion 3swe, the length L1 of the straight portion 3swl, and the like is small, and the tip width We and the gradient Gt that are in accordance with a required spread angle θ should be designed in addition to the waveguide length Lw described above.

Then, in examining the spread angle θ again, when the length L_{pd} from the LD chip to the reflective surface Fm in the beam center Cb is 0.5 mm and the spread angle θ is 30°, the minimum necessary length L_{pd} for the reflective surface Fm is 1.22 mm. In contrast, when the spread angle θ is narrowed down to 20°, the required length L_{pd} is 0.6 mm. Further, when the spread angle θ is narrowed down to 15°, the necessary length L_{pd} can be reduced down to 0.4 mm.

However, if the spread angle θ is to be further made narrower than 15°, it is necessary to set the tip width We to 0.4 μm or less, and it is difficult to suppress the amount of change Δθ even if the gradient Gt is made longer when manufacturing variation exists. On the other hand, in the case where the spread angle θ is set to 25°, the necessary length L_{pd} is enlarged up to 0.8 mm, but it is an allowable length, the difference between the incident angles is 50°, and the distribution of the reflectivity is also within an allowable range.

That is, the spread angle θ is set in a range of 15° to 25°, which is smaller than in the case where the SSC is not used but larger than in the case where the typical SSC used for omitting the lens system is used. Further, when the taper length Lt is set so that the gradient Gt falls within the range of 0.025±0.008, even if the tip width We changes within the range of manufacturing variation, the amount of change Δθ can be kept within the allowable range.

In particular, when the tip width We is set to 0.5 to 0.7 μm and the SSC is formed such that the gradient Gt is 0.018 to 0.033, the light can be emitted at the spread angle θ of 15° to 25°, preferably 20° to 23°. As a result, it is possible to effectively suppress both the amount of change Δθ and the distribution of the incident angles.

Variation

In the above embodiment, an example of the configuration of the SSC in which the width of the active layer portion is changed has been described. In the present variation, an example of forming an SSC using a transparent waveguide will be described. FIG. 5 is a cross-sectional view corresponding to FIG. 1A described in Embodiment 1 for explaining the configuration of the LD chip of the semiconductor laser device according to the variation. As shown in FIG. 5, when the waveguide portion 3swP is configured with the transparent waveguide, the manufacturing variation of the waveguide length LwP is larger than when it is configured with the active layer. However, even in this case, when the SSC is formed with the tip width We (0.5 to 0.7 μm) and the gradient Gt (0.018 to 0.033) described above, the light can be emitted with the spread angle θ of 15° to 25°, preferably 20° to 23°, while the amount of change Δθ is suppressed. As a result, the distribution of the incident angles can be suppressed, and the semiconductor laser device 10 having high reliability in a compact size can be achieved.

### Embodiment 2

In Embodiment 1, an example has been described in which the beam center is made horizontal with respect to the mounting surface and the PD chip is inclined at 45° with respect to the mounting surface, but this is not a limitation. In Embodiment 2, an example in which the beam center is inclined with respect to the mounting surface so that the beam is directed toward the mounting surface will be described.

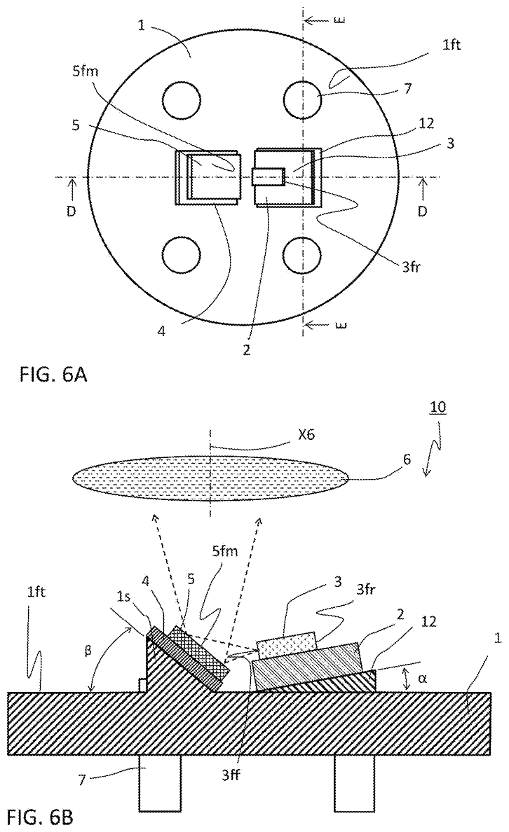

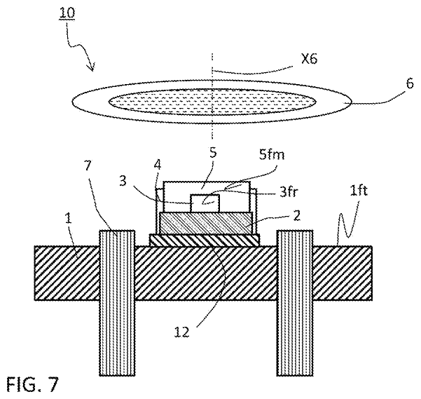

FIG. 6 and FIG. 7 are views for explaining a configuration of a semiconductor laser device according to Embodiment 2, and FIG. 6 includes a plan view (FIG. 6A) from the side of the mounting surface of the stem of the semiconductor laser device, in which the lens is excluded, and a view of a cross section (FIG. 6B) taken along the line D-D in FIG. 6A as the cross section that is perpendicular to the mounting surface of the stem and includes the beam center. Further, FIG. 7 is a view of a cross section taken along the line E-E in FIG. 6A as the cross section that is perpendicular to the mounting surface of the stem of the semiconductor laser device and perpendicular to an arrangement direction of the LD chip and the PD chip on the mounting surface. Note that, in the semiconductor laser device according to Embodiment 2 to Embodiment 4, the configuration of the LD chip itself is the same as that described in Embodiment 1, and FIG. 1 and FIG. 5 used in Embodiment 1 are referred to, and the description of similar components is omitted.

In the semiconductor laser device 10 according to Embodiment 2, as shown in FIG. 6A, FIG. 6B, and FIG. 7, a wedge-shaped block 12 having an inclination angle α is interposed between the submount 2 and the mounting surface 1ft. In Embodiment 1, since the LD chip 3 is placed flat on the mounting surface 1ft of the stem 1 via the submount 2, an inclination angle of the inclined portion is for mounting the PD chip 5 is set to 45°. In contrast, even in the case where the wedge-shaped block 12 is provided as in Embodiment 2, the same effects as described in Embodiment 1 can be obtained by setting an inclination angle 6 of the inclined portion is in accordance with the inclination angle α.

For example, it is assumed that the beam center Cb of the laser light emitted from the LD chip 3 is inclined by the inclination angle α with respect to the mounting surface 1ft by the wedge-shaped block 12. Then, by setting the inclination β of the inclined portion 1s with respect to the mounting surface 1 ft to a value obtained by subtracting the half angle of the inclination angle α from 45° (β=45°−α/2), it is possible to compensate the change in the direction of the reflected light to the lens 6 due to the inclination of the beam center Cb. In other words, the PD chip 5 can reflect the light such that the beam center Cb of the laser light emitted from the LD chip 3 is directed perpendicularly (parallel to an optical axis X6) toward the lens 6.

That is, even in such a configuration, when the SSC is formed with the tip width We (0.5 to 0.7 μm) and the gradient Gt (0.018 to 0.033) described in Embodiment 1, the light can be emitted with the spread angle θ of 15° to 25°, preferably 20° to 23°, while the amount of change Δθ is suppressed. As a result, the distribution of the incident angles can be suppressed, and the semiconductor laser device 10 having high reliability in a compact size can be achieved. Further, by having the inclination angle α, it is possible to shift the range of the incident angles in the PD chip 5 to the range of high angles in which high reflectivity is exhibited.

### Embodiment 3

In Embodiment 1 and Embodiment 2, the mounting surface of the stem is composed of only the flat surface and the portion such as the inclined portion protruding from the flat surface, but this is not a limitation. In Embodiment 3, an example in which a mounting surface has a portion recessed from the flat surface will be described.

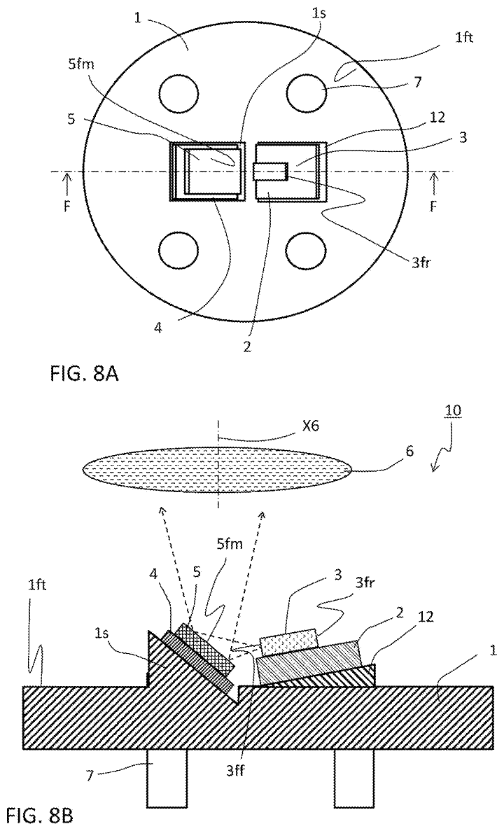

FIG. 8 includes views for explaining a configuration of a semiconductor laser device according to Embodiment 3, and these are a plan view (FIG. 8A) from the side of the mounting surface of the stem of the semiconductor laser device, in which the lens is excluded, and a view of a cross section (FIG. 8B) taken along the line F-F of FIG. 8A as the cross section perpendicular to the mounting surface of the stem and including the beam center.

In the semiconductor laser device 10 according to Embodiment 3, as shown in FIG. 8A and FIG. 8B, the wedge-shaped block 12 having the inclination angle α is interposed between the submount 2 and the mounting surface 1ft, and a portion on the side of the LD chip 3 in the inclined portion is is recessed from the mounting surface 1ft. Note that, in Embodiment 3, similar to Embodiment 2, the light emitted from the LD chip 3 is inclined (inclination angle α), and the inclination β in accordance with the inclination angle α is set in the inclined portion 1s.

As in Embodiment 3, by making the portion on the side of the LD chip 3 in the inclined portion is recessed from the mounting surface 1ft, it is possible to make the distance between the LD chip 3 and the PD chip 5 closer than in Embodiment 2, thereby reducing the required area for the PD chip 5. In addition, since the distance between the PD chip 5 and the mounting surface lft becomes shorter, the read length can be reduced, so that high-frequency characteristics can be expected to be improved. Note that, in the same manner as in Embodiment 1, even when the LD chip 3 is horizontally mounted on the mounting surface 1ft and the inclination angle α is set to 45°, the distance between the LD chip 3 and the PD chip 5 can be made close to each other, so that the required area of the PD chip 5 and the lead length can be reduced.

In addition to the effects described above, if the SSC is formed with the tip width We (0.5 to 0.7 μm) and the gradient Gt (0.018 to 0.033) described in Embodiment 1, the light can be emitted with the spread angle θ of 15° to 25°, preferably 20° to 23°, while the amount of change Δθ is suppressed. As a result, the distribution of the incident angles can be suppressed, and the semiconductor laser device 10 having high reliability in a compact size can be achieved.

### Embodiment 4

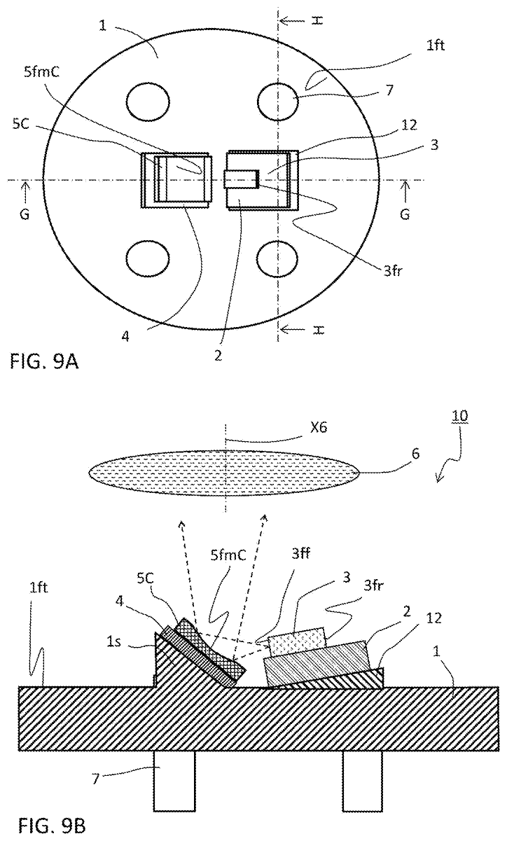

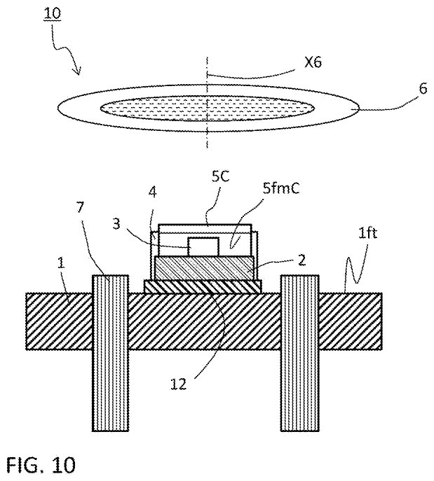

In each of the above embodiments, an example has been shown in which the reflective surface of the PD chip is the flat surface, but this is not a limitation. In Embodiment 4, an example in which the reflective surface of the PD chip is formed in a concave shape will be described. FIG. 9 and FIG. 10 are views for explaining a configuration of a semiconductor laser device according to Embodiment 4, and FIG. 9 includes a plan view (FIG. 9A) from the side of the mounting surface of the stem of the semiconductor laser device and a view of a cross section (FIG. 9B) taken along the line G-G of FIG. 9A as the cross section perpendicular to the mounting surface of the stem and including the beam center. FIG. 10 is a view of a cross section taken along the line H-H in FIG. 9A, which is perpendicular to the mounting surface of the stem of the semiconductor laser device and perpendicular to the arrangement direction of the LD chip and the PD chip on the mounting surface.

In the semiconductor laser device 10 according to Embodiment 4, as shown in FIG. 9A, FIG. 9B, and FIG. 10, the wedge-shaped block 12 having the inclination angle α is interposed between the submount 2 and the mounting surface 1ft, and a reflective surface 5fmC of a PD chip 5C is formed into a concave surface. Note that, in Embodiment 4, similar to Embodiment 2, the light emitted from the LD chip 3 is inclined (inclination angle α), and the inclination β in accordance with the inclination angle α is set in the inclined portion 1s.

By making the reflective surface 5fmC concave as in Embodiment 4, when the laser light emitted from the LD chip 3 is reflected, the concentrated light can be directed up in the vertical direction and the aberration of the light entering the lens 6 can be reduced. As a method for processing the concave surface, for example, isotropic etching by wet etching can be performed.

Similar to Embodiment 1, even when the LD chip 3 is horizontally mounted on the mounting surface 1ft and the inclination angle α is set to 45°, the same effects can be obtained. Further, when, at the tip of the inclined portion 1s, the recess is formed from the mounting surface 1ft as in Embodiment 3, the distance between the LD chip 3 and the PD chip 5 can be made close to each other, so that the required area of the PD chip 5 and the lead length can be reduced.

In addition to the above effects, when the SSC is formed with the tip width We (0.5 to 0.7 μm) and the gradient Gt (0.018 to 0.033) described in Embodiment 1, the light can be emitted with the spread angle θ of 15° to 25°, preferably 20° to 23°, while the amount of change Δθ is suppressed. As a result, the distribution of the incident angles can be suppressed, and the semiconductor laser device 10 having high reliability in a compact size can be achieved.

### Embodiment 5

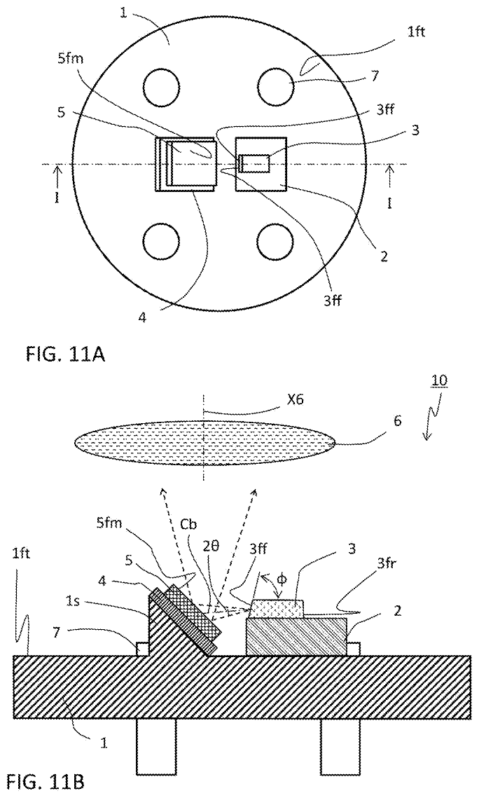

In Embodiment 2 to Embodiment 4, the LD chip is disposed on the inclined surface in order to incline the beam center toward the mounting surface, but this is not a limitation. In Embodiment 5, an example will be described in which the beam center is inclined toward the mounting surface by forming the front end face of the LD chip obliquely. FIG. 11 includes views for explaining a configuration of a semiconductor laser device according to Embodiment 5, and they are a plan view (FIG. 11A) from the side of the mounting surface of the stem of the semiconductor laser device, in which the lens is excluded, and a view of a cross section (FIG. 11B) taken along line I-I of FIG. 11A as the cross section perpendicular to the mounting surface of the stem and including the beam center. Note that, in the semiconductor laser device according to Embodiment 5, the configuration other than the LD chip is the same as that described in Embodiment 1, and FIG. 1 and FIG. 3 to FIG. 5 used in Embodiment 1 are referred to, and the description of similar components is omitted.

In the semiconductor laser device 10 according to Embodiment 5, as shown in FIG. 11A and FIG. 11B, the front end face 3ff of the LD chip 3 is processed obliquely with respect to the lamination direction of the chip (the vertical direction in FIG. 11B). The front end face 3ff is processed, for example, by anisotropic etching using an etchant such as HBr, sulfuric acid or tartaric acid and is etched so as to have an inclination ϕ of 54.7° at a maximum with respect to the substrate. Since the refractive index of the waveguide portion 3sw is about 3.2 and the refractive index of air is about one, the beam center Cb can be inclined toward the mounting surface 1ft such that the beam is directed toward the mounting surface 1ft.

The inclination angle α of the beam center Cb fixed by the formation of the inclined front end face 3ff is calculated by using an equation (3) on the basis of the etching angle ϕ, a refractive index n_{w} of the waveguide portion 3sw or an end face coating film (not shown), and a refractive index nₓ of an external medium for the LD chip 3.

sin(α)=(n_{w}/nₓ)×sin (90°−ϕ) (3)

Since the inclined front end face 3ff is formed in the way described above, the beam can be inclined toward the mounting surface 1ft even though the LD chip 3 is placed flat as in Embodiment 1. As described in Embodiment 2 to Embodiment 4, by setting the inclination angle β of the inclined portion is in accordance with the inclination angle α in consideration of the inclination of the front end face 3ff, it is possible to obtain the same effects as described in Embodiment 1.

For example, by processing the front end face 3ff of the LD chip 3 obliquely, the beam center Cb of the laser light emitted from the LD chip 3 placed flat inclines by the inclination angle α with respect to the mounting surface 1ft. In this case, by setting the inclination β of the inclined portion is with respect to the mounting surface 1ft to a value (β=45°−α/2) obtained by subtracting the half angle of the inclination angle α from 45°, it is possible to compensate the change in the direction of the reflected light to the lens 6 due to the inclination of the beam center Cb. In other words, the PD chip 5 can reflect the light such that the beam center Cb of the laser light emitted from the LD chip 3 is directed perpendicularly (parallel to the optical axis X6) toward the lens 6.

That is, even in such a configuration, since the SSC is formed in the LD chip 3 with the tip width We (0.5 to 0.7 μm) and the gradient Gt (0.018 to 0.033), the light can be emitted with the spread angle θ of 15° to 25°, preferably 20° to 23°, while the amount of change Δθ is suppressed. As a result, the distribution of the incident angles can be suppressed, and the semiconductor laser device 10 having high reliability in a compact size can be achieved. Further, as described in Embodiment 2, by having the inclination angle α, it is possible to shift the range of the incident angles in the PD chip 5 to the range of high angles in which high reflectivity is exhibited.

### Embodiment 6

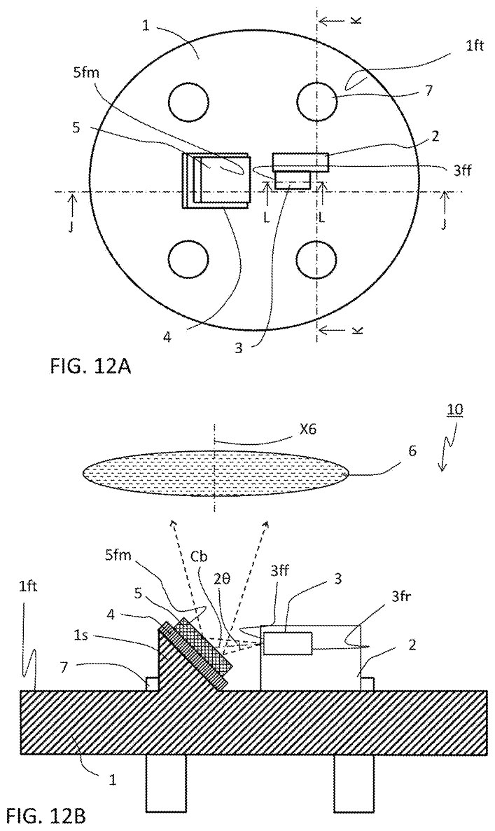

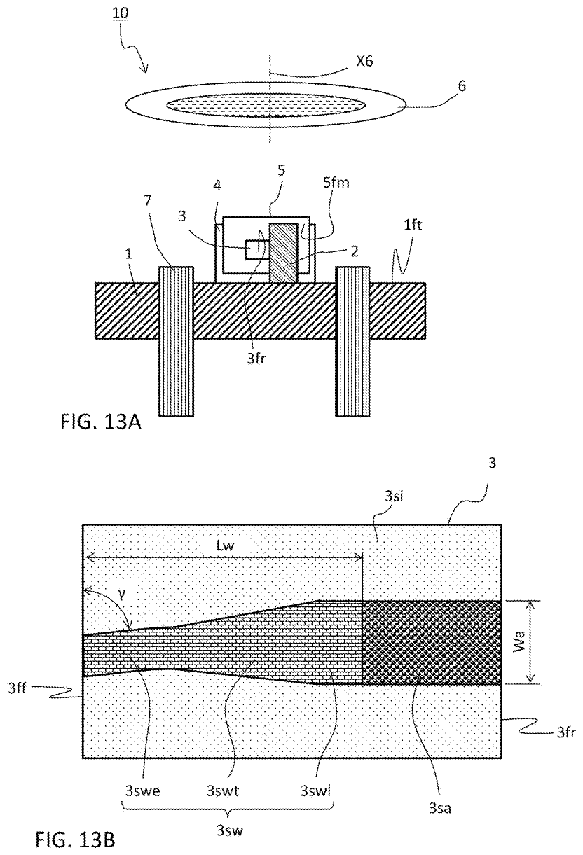

Embodiment 5 shows an example in which the beam center can be inclined toward the mounting surface by forming the LD chip with the front end face inclined even when the LD chip is placed flat. In Embodiment 6, an example of adjusting the direction of the beam center by curving the tip portion of the waveguide will be described. FIG. 12 and FIG. 13 are views for explaining a configuration of a semiconductor laser device according to Embodiment 6. FIG. 12 includes a plan view (FIG. 12A) from the side of the mounting surface of the stem of the semiconductor laser device, in which the lens is excluded, and a view of a cross section (FIG. 12B) taken along the line J-J in FIG. 12A as the cross section perpendicular to the mounting surface of the stem and parallel to the beam center, and FIG. 13 includes a view of a cross-section (FIG. 13A) taken along the line K-K in FIG. 12A as the view of a cross section perpendicular to the mounting surface of the stem of the semiconductor laser device and perpendicular to the arrangement direction of the LD chip and the PD chip on the mounting surface, and a cross section (FIG. 13B) taken along the line L-L in FIG. 12A to show a shape of a waveguide portion of the LD chip.

In the semiconductor laser device according to Embodiment 6, the configuration other than the LD chip and the submount for the LD chip is the same as that described in Embodiment 1, and the description of similar components will be omitted.

In the semiconductor laser device 10 according to Embodiment 6, as shown in FIG. 12 and FIG. 13A, the submount 2 on which the LD chip 3 is mounted is placed vertically with respect to the mounting surface 1ft such that the lamination direction of the chip (chip lamination direction) is parallel to the mounting surface 1ft. In the LD chip 3 as shown in FIG. 13B, the waveguide portion 3sw is curved in a plane perpendicular to the lamination direction of the chip in the vicinity of the front end face 3ff so that the beam can be directed toward the mounting surface 1ft when the LD chip 3 is mounted on the submount 2. The inclination angle α of the beam center Cb is calculated by using the following equation (4) on the basis of an angle γ formed between the center of advance in the waveguide portion 3sw and the front end face 3ff, the refractive index n_{w} of the wave guide portion 3sw or the end surface coating film (not shown), and the refractive index nₓ of the external medium for the LD chip 3.

sin (α)=(n_{w}/dₓ)×sin (90°−γ) (4)

Since the tip portion of the waveguide portion 3sw is curved so as to be inclined with respect to the front end face 3ff, and the submount 2 on which the LD chip 3 is mounted so as to be attached laterally is vertically placed with respect to the mounting surface, the beam can be inclined toward the mounting surface 1ft. Therefore, as described in Embodiment 2 to Embodiment 4, by setting the inclination β of the inclined portion is in accordance with the inclination angle α in consideration of the angle γ, it is possible to obtain the same effects as described in Embodiment 1.

For example, since the tip portion of the waveguide portion 3sw is curved in the LD chip 3, which is mounted on the submount 2 on the vertical surface with respect to the mounting surface 1ft so as to be laterally attached thereto, the beam center Cb of the laser light emitted from the LD chip 3 inclines by the inclination angle α with respect to the mounting surface 1ft. In this case, by setting the inclination β of the inclined portion is with respect to the mounting surface 1ft to a value (β=45°−α/2) obtained by subtracting the half angle of the inclination angle α from 45°, it is possible to compensate the change in the direction of the reflected light to the lens 6 due to the inclination of the beam center Cb. In other words, the PD chip 5 can reflect the light such that the beam center Cb of the laser light emitted from the LD chip 3 is directed perpendicularly (parallel to the optical axis X6) toward the lens 6.

That is, even in such a configuration, since the SSC is formed in the LD chip 3 with the tip width We (0.5 to 0.7 μm) and the gradient Gt (0.018 to 0.033), the light can be emitted with the spread angle θ of 15° to 25°, preferably 20° to 23°, while the amount of change Δθ is suppressed. As a result, the distribution of the incident angles can be suppressed, and the semiconductor laser device 10 having high reliability in a compact size can be achieved.

### Embodiment 7

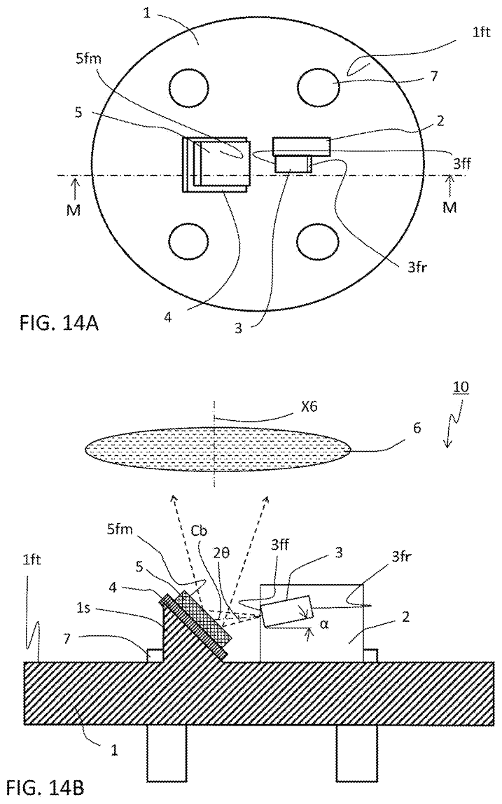

In the above Embodiment 5 and Embodiment 6, an example in which the adjustment in the structure of the LD chip is made in order to incline the beam toward the mounting surface has been described. In a semiconductor laser device according to Embodiment 7, an example in which the inclination of the beam is adjusted in accordance with a mounting direction of the LD chip will be described. FIG. 14 includes views for explaining a configuration of a semiconductor laser device according to Embodiment 7, and they are a plan view (FIG. 14A) from the side of the mounting surface of the stem of the semiconductor laser device, in which the lens is excluded, and a view of a cross section (FIG. 14B) taken along the line M-M in FIG. 14A as the cross section perpendicular to the mounting surface of the stem and parallel to the beam center. In the semiconductor laser device according to Embodiment 7, the configuration other than the mounting direction of the LD chip is the same as that described in Embodiment 1, and FIG. 1 and FIG. 5 used in Embodiment 1 are referred to, and the description of similar components is omitted.

In the semiconductor laser device 10 according to Embodiment 7, as shown in FIG. 14A and FIG. 14B, the lamination direction of the chip is made parallel to the mounting surface 1ft, and the LD chip 3 is attached to the submount 2 laterally such that the beam center Cb is inclined by the inclination angle α with respect to the mounting surface 1ft. In Embodiment 1, since the LD chip 3 is placed flat on the mounting surface 1ft of the stem 1 via the submount 2, the inclination angle of the inclined portion is for mounting the PD chip 5 is set to 45°. In contrast, even in the case where the LD chip 3 is attached on the submount 2 laterally by the inclination angle α with respect to the mounting surface 1ft as in Embodiment 7, the same effects as described in Embodiment 1 can be obtained by setting the inclination β of the inclined portion is in accordance with the inclination angle α.

For example, when the LD chip 3 is attached to the submount 2 laterally so as to be inclined by an inclination angle α with respect to the mounting surface 1ft, the beam center Cb of the laser light emitted from the LD chip 3 inclines by the inclination angle α with respect to the mounting surface 1ft. Then, by setting the inclination β of the inclined portion is with respect to the mounting surface 1ft to a value obtained by subtracting the half angle of the inclination angle α from 45° (β=45°−α/2), it is possible to compensate the change in the direction of the reflected light to the lens 6 due to the inclination of the beam center Cb. In other words, the PD chip 5 can reflect the light such that the beam center Cb of the laser light emitted from the LD chip 3 is directed perpendicularly (parallel to an optical axis X6) toward the lens 6.

That is, even in such a configuration, since the SSC is formed in the LD chip 3 with the tip width We (0.5 to 0.7 μm) and the gradient Gt (0.018 to 0.033), the light can be emitted with the spread angle θ of 15° to 25°, preferably 20° to 23°, while the amount of change Δθ is suppressed. As a result, the distribution of the incident angles can be suppressed, and the semiconductor laser device 10 having high reliability in a compact size can be achieved.

Note that, although various exemplary embodiments and examples are described in the present application, various features, aspects, and functions described in one or more embodiments are not inherent in a particular embodiment and can be applicable alone or in their various combinations to each embodiment. Accordingly, countless variations that are not illustrated are envisaged within the scope of the art disclosed herein. For example, the case where at least one component is modified, added or omitted, and the case where at least one component is extracted and combined with a component in another embodiment are included.

For example, an example has been shown in which the PD chip 5 is disposed via the inclined portion 1s, and the LD chip 3 is disposed via the mounting surface 1ft of the stem 1 or via the wedge-shaped block 12, but this is not a limitation. The PD chip 5 may be disposed via a block such as the wedge-shaped block 12 described in Embodiment 2, or the LD chip 3 may be disposed by forming an inclined portion such as the inclined portion 1s. Further, even in the case where the LD chip 3 itself is adjusted to a structure in which the beam is inclined as in Embodiment 5 and Embodiment 6, a member for adjusting the mounting direction of the LD chip 3 may be combined with the structure as in Embodiment 2 to Embodiment 4 and Embodiment 7.

As described above, the semiconductor laser device 10 according to each embodiment includes the lens 6, the stem 1 disposed so as to be opposed to the lens 6 with a space therebetween, the semiconductor laser element (LD chip 3) to emit the laser light with the beam center Cb directed along the opposed surface (mounting surface 1ft) of the stem 1 to the lens 6, and the photodiode element (PD chip 5) having the reflective surface 5fm formed with the dielectric multilayer film on its surface, reflecting the laser light emitted from the semiconductor laser element (LD chip 3) toward the lens 6, and measuring the amount of the laser light, wherein the semiconductor laser element (LD chip 3) is provided with a waveguide portion (3sw) having the tip portion (3swe) that is formed at the end portion on the emission side (on the side of the front end face 3ff) and has the width (We) of 0.5 to 0.7 μm, and having the tapered portion (3swe) that is connected to the tip portion (3swe) and becomes narrower toward the tip portion (3swe) at the gradient (gradient Gt) of 0.018 to 0.033, so that the amount of change Δθ can be suppressed and the light is emitted with the spread angle θ being narrowed, although not to the extent that the lens system is omitted. As a result, the distribution of the incident angles (incident angle Aib to incident angle Aiu) can be suppressed, and the semiconductor laser device 10 having high reliability in a compact size can be achieved.

When the semiconductor laser element (LD chip 3) is adjusted so as to emit the laser light at the spread angle θ of 15° to 25° with respect to the beam center Cb, the amount of change Δθ due to the manufacturing variation is not much larger, and the distribution of the incident angles and the required area of the PD chip 5 can be effectively suppressed.

In particular, when the spread angle θ is 20° to 23°, the amount of change Δθ due to the manufacturing variation can be suppressed more reliably, and the distribution of the incident angles and the required area of the PD chip 5 can be effectively suppressed.

Further, even when the semiconductor laser element (LD chip 3) emits the light such that the beam center Cb thereof is directed toward the opposed surface (mounting surface 1ft) at the inclination angle α, and the photodiode element (PD chip 5) is disposed such that the reflective surface 5fm is inclined at the angle (inclination β) of 45°−α/2 with respect to the opposed surface (mounting surface 1ft), the effects described above can be obtained.

Since the front end face 3ff of the semiconductor laser device (LD chip 3) is inclined with respect to the lamination direction of the chip, the beam center Cb can be inclined toward the mounting surface 1ft even when the chip is placed flat.

For example, the semiconductor laser element (LD chip 3) is attached laterally on the submount 2 and is disposed such that the lamination direction of the chip is parallel to the opposed surface (mounting surface 1ft), so that the inclination angle α can be freely adjusted.

In this case, when the semiconductor laser element (LD chip 3) is configured such that the waveguide portion 3sw is curved in the plane perpendicular to the lamination direction of the chip, the beam center Cb can be inclined toward the mounting surface 1ft even when the semiconductor laser element is attached truly in the lateral direction.

When the end portion of the photodiode element (PD chip 5) on the side closer to the semiconductor laser element (LD chip 3) is disposed in the inclined portion is that extends to the position of the recess formed from the opposed surface (mounting surface 1ft), the distance between the LD chip 3 and the PD chip 5 can be made closer, and the required area of the PD chip 5 can be reduced. Further, since the distance between the PD chip 5 and the mounting surface lft is made shorter, the lead length can be reduced, so that the high-frequency characteristics can be expected to be improved.

When the reflective surface 5fm C is formed in the concave shape, the aberration of the light entering the lens 6 can be reduced.

Even when the waveguide portion 3swp is composed of the transparent waveguide, the effects described above can be achieved.

### DESCRIPTION OF REFERENCE NUMERALS AND SIGNS

1: stem, 1ft: mounting surface (opposed surface), 10: semiconductor laser device, 3: LD chip (semiconductor laser element), 3ff: front end face, 3sa: active layer, 3sw: waveguide portion, 3swP: waveguide portion, 3swe: tip portion, 3swt: tapered portion, 5: PD chip (photodiode element), 5fm: reflective surface, 6: lens, Cb: beam center, Gt: gradient, α: inclination angle, β: inclination, ϕ: inclination, θ: spread angle.

1. A semiconductor laser device, comprising:
a lens;
a stem disposed so as to be opposed to the lens with a space therebetween;
a semiconductor laser element to emit laser light with a beam center directed along an opposed surface of the stem to the lens; and
a photodiode element having a reflective surface formed with a dielectric multilayer film on its surface, reflecting the laser light emitted from the semiconductor laser element toward the lens, and measuring an amount of the laser light, wherein
the semiconductor laser element is provided with a waveguide portion having a tip portion that is formed at an end portion on an emission side of the laser light and has a width of 0.5 to 0.7 μm, and having a tapered portion that is connected to the tip portion and becomes narrower toward the tip portion at a gradient of 0.018 to 0.033.

2. The semiconductor laser device according to claim 1, wherein the semiconductor laser element emits the laser light at a spread angle of 15° to 25° with respect to the beam center.

3. The semiconductor laser device according to claim 2, wherein the spread angle is 20° to 23°.

4.-10. (canceled)

11. The semiconductor laser device according to claim 1, wherein the semiconductor laser element emits the light such that the beam center thereof is directed toward the opposed surface at an inclination angle α, and the photodiode element is disposed such that the reflective surface is inclined at an angle of 45°−α/2 with respect to the opposed surface.

12. The semiconductor laser device according to claim 2, wherein the semiconductor laser element emits the light such that the beam center thereof is directed toward the opposed surface at an inclination angle α, and the photodiode element is disposed such that the reflective surface is inclined at an angle of 45°−α/2 with respect to the opposed surface.

13. The semiconductor laser device according to claim 3, wherein the semiconductor laser element emits the light such that the beam center thereof is directed toward the opposed surface at an inclination angle α, and the photodiode element is disposed such that the reflective surface is inclined at an angle of 45°−α/2 with respect to the opposed surface.

14. The semiconductor laser device according to claim 11, wherein a front end face of the semiconductor laser element is inclined with respect to a lamination direction of a chip.

15. The semiconductor laser device according to claim 12, wherein a front end face of the semiconductor laser element is inclined with respect to a lamination direction of a chip.

16. The semiconductor laser device according to claim 13, wherein a front end face of the semiconductor laser element is inclined with respect to a lamination direction of a chip.

17. The semiconductor laser device according to claim 11, wherein the semiconductor laser element is disposed such that a lamination direction of a chip is parallel to the opposed surface.

18. The semiconductor laser device according to claim 12, wherein the semiconductor laser element is disposed such that a lamination direction of a chip is parallel to the opposed surface.

19. The semiconductor laser device according to claim 13, wherein the semiconductor laser element is disposed such that a lamination direction of a chip is parallel to the opposed surface.

20. The semiconductor laser device according to claim 17, wherein the waveguide portion of the semiconductor laser element is curved in a plane perpendicular to the lamination direction of the chip.

21. The semiconductor laser device according to claim 18, wherein the waveguide portion of the semiconductor laser element is curved in a plane perpendicular to the lamination direction of the chip.

22. The semiconductor laser device according to claim 19, wherein the waveguide portion of the semiconductor laser element is curved in a plane perpendicular to the lamination direction of the chip.

23. The semiconductor laser device according to claim 1, wherein an end portion of the photodiode element on a side closer to the semiconductor laser element is disposed in an inclined portion that extends to a position of a recess formed from the opposed surface.

24. The semiconductor laser device according to claim 11, wherein an end portion of the photodiode element on a side closer to the semiconductor laser element is disposed in an inclined portion that extends to a position of a recess formed from the opposed surface.

25. The semiconductor laser device according to claim 1, wherein the reflective surface is formed in a concave shape.

26. The semiconductor laser device according to claim 11, wherein the reflective surface is formed in a concave shape.

27. The semiconductor laser device according to claim 1, wherein the waveguide portion is composed of a transparent waveguide.
